(19) United States
(12) Patent Application Publication
(10) Pub. No.: US 2011/0073183 A1
(43) Pub. Date: Mar. 31, 2011

(54) REFLECT-ARRAY LENS FOR SOLAR CELL AND SOLAR CELL MODULE HAVING REFLECT-ARRAY LENS

(75) Inventors: Woo Jin BYUN, Daejeon (KR); Min Soo Kang, Daejeon (KR); Kwang Seon Kim, Daejeon (KR); Bong Su Kim, Daejeon (KR)

(73) Assignee: ELECTRONICS AND TELECOMMUNICATION RESEARCH INSTITUTE, Daejeon (KR)

(21) Appl. No.: 12/889,525

(22) Filed: Sep. 24, 2010

(30) Foreign Application Priority Data
Sep. 25, 2009 (KR) 10-2009-0091358
Sep. 1, 2010 (KR) 10-2010-0085687

(51) Int. Cl. H01L 31/0232; G02B 27/14

(52) U.S. Cl. 136/259; 359/627

(57) ABSTRACT

Disclosed are a reflect-array lens (or a planar lens) and a solar cell module having the same. The reflect-array lens for a solar cell includes: a planar dielectric substrate having a first permittivity, wherein a plurality of recesses are formed on one surface of the planar dielectric substrate and filled with a dielectric having a second permittivity different from the first permittivity. The reflect-array lens can be easily fabricated and has an excellent concentration degree, and the solar cell module having the reflect-array lens has improved photoelectric conversion efficiency.

### CROSS-REFERENCE TO RELATED APPLICATIONS

This application claims the priority of Korean Patent Application No. 10-2009-0091358 filed on Sep. 25, 2009, and Korean Patent Application No. 10-2010-0085687 filed on Sep. 1, 2010, in the Korean Intellectual Property Office, the disclosure of which is incorporated herein by reference.

### BACKGROUND OF THE INVENTION

1. Field of the Invention

The present invention relates to a reflect-array lens (or a planar lens) and a solar cell module having the same and, more particularly, to a reflect-array lens for a solar cell capable of improving an energy conversion efficiency and a solar cell module having the reflect-array lens.

2. Description of the Related Art

A solar cell is an element for converting light energy into electrical energy. However, because the solar cell does not have good energy conversion efficiency, a usage rate of the solar cell is low compared with a general secondary or rechargeable battery.

Research into improving an energy conversion efficiency of the solar cell is actively ongoing, and one of the research fields relates to a method for configuring a solar cell module by using a lens.

One of the most generally known methods for improving the energy conversion efficiency is disposing solar cells on and along a parabola surface. This structure is largely employed to implement a high power solar cell module, which has been commercialized and installed.

However, the structure in which solar cells are disposed on and along a parabola surface is disadvantageous in that it cannot be employed for a device having a limited area and external appearance such as a mobile terminal, and the like, using a solar cell as a power supply source.

One of the methods that can enhance energy conversion efficiency by complementing the shortcomings thereof is to use a lens. The use of a lens can improve a concentration degree by about hundreds times. For example, when the use of a lens having a concentration degree of 500 times requires a solar cell having an area of 1 cm², the area of a solar cell required for obtaining the same energy efficiency while the lens is not in use can be approximately 500 cm².

A convex lens and a Fresnel lens are generally used to enhance a concentration degree of a solar cell.

However, the use of a convex lens makes it difficult to design a curved surface of the convex lens and increases the overall thickness of the lens due to the thickness of the curved surface, and the use of a Fresnel lens makes it difficult to elaborately process the shape of the lens section.

### SUMMARY OF THE INVENTION

An aspect of the present invention provides a reflect-array lens (or a planar lens) for a solar cell which can be easily fabricated and has an improved degree of concentration.

Another aspect of the present invention provides a solar cell module having a reflect-array lens which has improved photoelectric conversion efficiency.

According to an aspect of the present invention, there is provided a reflect-array lens for a solar cell including: a planar dielectric substrate having a first permittivity, wherein a plurality of recesses are formed on one surface of the planar dielectric substrate and filled with a dielectric having a second permittivity different from the first permittivity.

The width of each of the plurality of recesses may be equal to or larger than a half of the wavelength of light made incident to the reflect-array lens for a solar cell.

A reflection member for reflecting incident light may be installed on the surface opposed to the one surface of the planar dielectric substrate including the plurality of recesses formed thereon.

An antenna pattern may be formed at an outer side of the reflection member formed on the surface opposed to the one surface of the planar dielectric substrate including the plurality of recesses formed thereon.

The interval between adjacent recesses among the plurality of recesses may be smaller than the width of each recess.

According to an aspect of the present invention, there is provided a solar cell module including: a reflect-array lens including a planar dielectric substrate having a first permittivity and having a plurality of recesses formed thereon and filled with a dielectric having a second permittivity different from the first permittivity; and a solar cell installed to be spaced apart by a focal distance from the reflect-array lens and converting light concentrated through the reflect-array lens into an electrical signal.

A reflection member for reflecting incident light may be installed on the surface opposed to the one surface of the planar dielectric substrate including the plurality of recesses formed thereon.

An antenna pattern may be formed at an outer side of the reflection member formed on the surface opposed to the one surface of the planar dielectric substrate including the plurality of recesses formed thereon.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a sectional view showing the structure of a reflect-array lens (or a planar lens) for a solar cell according to an exemplary embodiment of the present invention;

FIG. 2 is a sectional view showing the structure of a reflect-array lens for a solar cell according to another exemplary embodiment of the present invention;

FIG. 3 is a sectional view showing the structure of a reflect-array lens for a solar cell according to another exemplary embodiment of the present invention;

FIG. 4 is a conceptual view for explaining the constitution and operation of a solar cell module having a reflect-array lens according to an exemplary embodiment of the present invention; and

FIG. 5 is a conceptual view for explaining the constitution and operation of a solar cell module having a reflect-array lens according to another exemplary embodiment of the present invention.

### DETAILED DESCRIPTION OF THE PREFERRED EMBODIMENT

The present invention may be modified variably and may have various embodiments, particular examples of which will be illustrated in drawings and described in detail.

However, it should be understood that the following exemplifying description of the invention is not intended to restrict the invention to specific forms of the present invention but rather the present invention is meant to cover all modifications, similarities and alternatives which are included in the spirit and scope of the present invention.

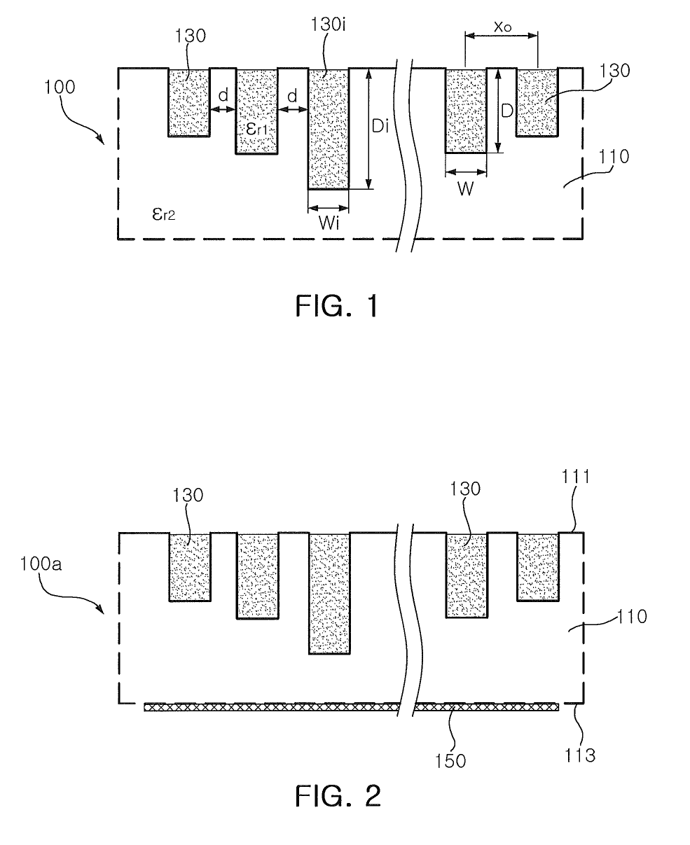

FIG. 1 is a sectional view showing the structure of a reflect-array lens for a solar cell according to an exemplary embodiment of the present invention.

With reference to FIG. 1, a reflect-array lens (or a planar lens) 100 for a solar cell includes a plurality of recesses 130 formed on a planar dielectric substrate 110 having a relative permittivity ∈ᵣ₂ by using an etching process. The plurality of recesses 130 are filled with a dielectric substance (e.g., air or a transparent material) having a relative permittivity ∈ᵣ₁. Here, the planar dielectric substrate 110 may be made of universal glass or a transparent plastic material having a permittivity ranging from 3 to 10.

Among the plurality of recesses, ith recess 130i has a width Wi and a depth Di. Here, the relative permittivity ∈ᵣ₁ of the recess may have a different value from the relative permittivity ∈ᵣ₂ of the dielectric substrate.

The width (W) of the recess may be formed substantially to have a size equal to a half (λ/2) of the wavelength (λ) of light made incident to the reflect-array lens 100. For example, when incident light is visible light and has a wavelength of 700 nm, the width (W) of each recess 130 may be 350 nm. The distance (d) between adjacent recesses 130 may be smaller than the width (λ/2) of the recesses 130. Here, the smaller the distance (d) between the adjacent recesses 130, the better the concentration capability. In FIG. 1, x0 refers to the distance between the centers of two adjacent recesses.

Depths (D) of the respective recesses 130 may be different to allow light made incident to the respective recesses to be concentrated on a solar cell positioned at a focal distance. A cross section of each recess may have a quadrangular shape. However, the present invention is not limited thereto, and the cross section of each recess may have various shapes other than the rectangular shape.

When the planar dielectric substrate 110 has a circular shape, the respective recesses positioned at the same distance from the center of the planar dielectric substrate may have the same width (W) and depth (D), or the depths of the respective recesses 130 may be different according to phases by using the characteristics that the phase increases as the depth of the recess is longer.

FIG. 2 is a sectional view showing the structure of a reflect-array lens for a solar cell according to another exemplary embodiment of the present invention.

With reference to FIG. 2, a reflect-array lens 100a for a solar cell according to another exemplary embodiment of the present invention further includes a reflection member 150 for reflecting light to one surface of the reflect-array lens 100 for a solar cell illustrated in FIG. 1.

The reflection member 150 may be installed on the side 113 opposed to a surface 111 of the planar dielectric substrate on which the recesses 130 are formed, and may be made of a mirror material, a material obtained by coating amalgam on glass, or the like.

The reflect-array lens 100a for a solar cell as illustrated in FIG. 2 may be used when light is concentrated in a direction opposite to a direction in which light is made incident to the reflect-array lens.

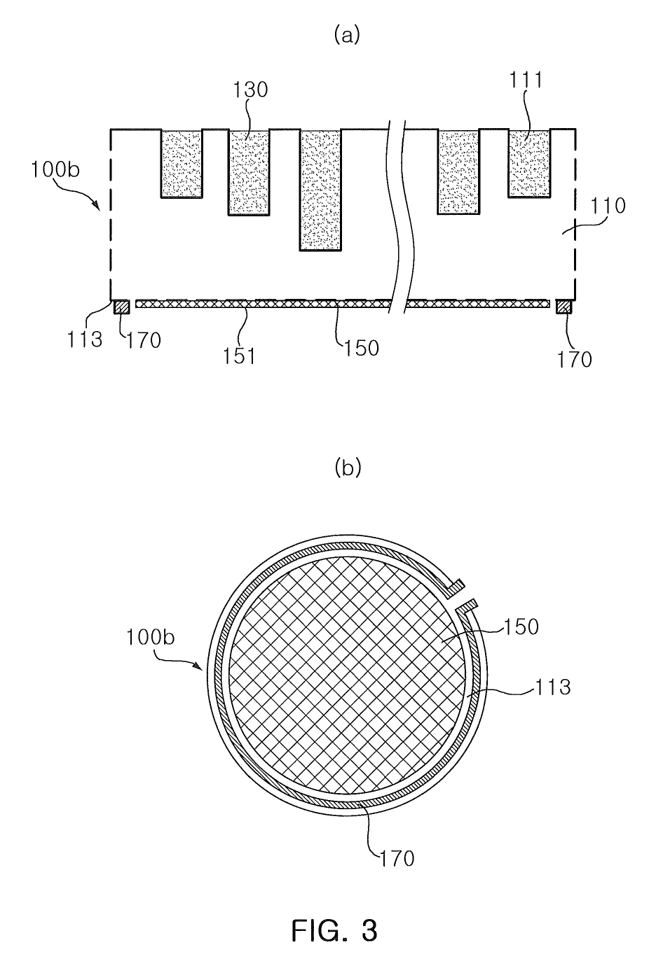

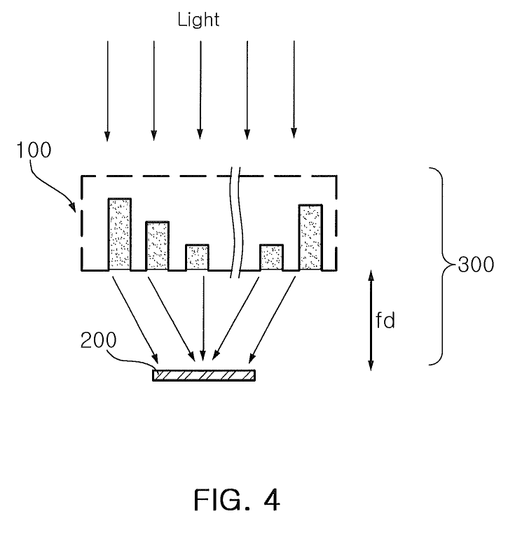

FIG. 3 is a sectional view showing the structure of a reflect-array lens for a solar cell according to another exemplary embodiment of the present invention.

With reference to FIG. 3, a reflect-array lens 100b for a solar cell according to another exemplary embodiment of the present invention further includes an antenna 170 in the reflect-array lens 100b for a solar cell illustrated in FIG. 2.

In detail, the antenna 170 pattern may be formed on the side 113 where the reflection member 150 is installed, which is opposed to the surface 111 of the planar dielectric substrate 110 where the recesses are formed, and in this case, the antenna 170 may be formed around the reflection member 150 so as not to overlap with the reflection member 150, or may be formed on a surface 151 of the reflection member 150.

For example, as shown in FIG. 3(b), a lower plan view of the reflect-array lens 100b, the antenna 170 may be installed by patterning a conductive member on outer edges of the reflection member 150 installed on the side 113 opposed to the surface of the planar dielectric substrate 110 where the recesses are formed. In this case, the antenna 170 may perform the function of a loop antenna or a folded dipole antenna.

When the reflect-array lens 100b for a solar cell having the antenna illustrated in FIG. 3 is used for a small, thin device such as a mobile terminal, or the like, because it does not need a space for installing the antenna, the degree of freedom enjoyed by a designer can be enhanced.

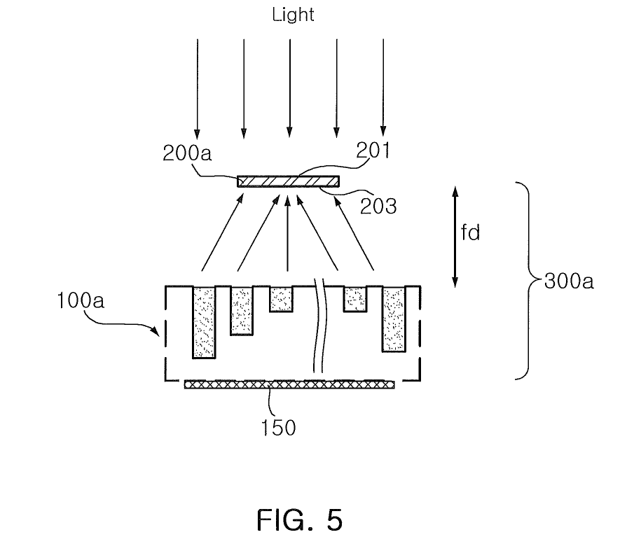

FIG. 4 is a conceptual view for explaining the constitution and operation of a solar cell module having a reflect-array lens according to an exemplary embodiment of the present invention.

With reference to FIG. 4, a solar cell module 300 according to an exemplary embodiment of the present invention includes the reflect-array lens 100 and a solar cell 200 installed space apart by a focal distance fd from the reflect-array lens 100.

Here, the relationship among the focal distance fd, the depth (D) of a certain recess, the depth Di of the ith recess, and the distance x0 between the centers of adjacent recesses may be represented by Equation 1 shown below, and in this case, an optimized focal distance may be determined by repeatedly performing a three-dimensional simulation.

$$D = {D}_{i} - \frac{1}{4 {f}_{d}} {x}_{0}^{2} \qquad [ Equation 1 ]$$

The reflect-array lens 100 may be configured as the reflect-array lens illustrated in FIG. 1, and because the solar cell 200 installed spaced apart by the focal distance fd from the reflect-array lens 100 receives light concentrated through the reflect-array lens 100 having a wider light receiving area, it can receive light with a very high concentration degree, and thus, a photoelectric conversion efficiency of the solar cell 200 can be improved.

FIG. 5 is a conceptual view for explaining the constitution and operation of a solar cell module having a reflect-array lens according to another exemplary embodiment of the present invention.

With reference to FIG. 5, a solar cell module 300a according to the present exemplary embodiment includes a solar cell 200a installed spaced apart by the focal distance fd from the reflect-array lens 100a including the reflection member 150 installed thereon as illustrated in FIG. 2.

Here, the solar cell 200a may be configured as a double-sided solar cell that can receive light from upper and lower surfaces 201 and 203 thereof. The upper surface 201 of the solar cell 200a may receive light directly incident thereon and perform photoelectric conversion, and the lower surface 203 of the solar cell 200a may receive light reflected through the reflect-array lens 100a having the reflection member 150 and perform photoelectric conversion.

Thus, when the double-sided solar cell 200a as shown in FIG. 5 is provided, preferably, the reflect-array lens 100a is installed at a position from which the reflect-array lens 100a can provide reflected light in a direction opposite to the direction in which light is directly made incident to the solar cell 200a.

As set forth above, in the reflect-array lens for a solar cell and the solar cell module having the reflect-array lens according to exemplary embodiments of the invention, a plurality of recesses having the width and depth corresponding to the focal distance are formed on the planar dielectric substrate and spaced apart by a focal distance from the solar cell. Thus, the lens can be fabricated to have a high concentration degree through a simpler process compared with the related art convex lens or Fresnel lens, and accordingly, the fabrication unit cost can be reduced. Also, because the solar cell module having the reflect-array lens has a simpler structure, it can be suitable to be applied for a device having a great number of restrictions in designing an external appearance, such as a mobile terminal, and the like, and the degree of user design flexibility can be improved.

While the present invention has been shown and described in connection with the exemplary embodiments, it will be apparent to those skilled in the art that modifications and variations can be made without departing from the spirit and scope of the invention as defined by the appended claims.

What is claimed is:

1. A reflect-array lens for a solar cell comprising:
a planar dielectric substrate having a first permittivity,
wherein a plurality of recesses are formed on one surface of the planar dielectric substrate and filled with a dielectric having a second permittivity different from the first permittivity.

2. The reflect-array lens of claim 1, wherein the width of each of the plurality of recesses is equal to or larger than a half of the wavelength of light made incident to the reflect-array lens for a solar cell.

3. The reflect-array lens of claim 1, wherein the depth of each of the plurality of recesses has a different length.

4. The reflect-array lens of claim 1, wherein a reflection member for reflecting incident light is installed on the surface opposed to the one surface of the planar dielectric substrate including the plurality of recesses formed thereon.

5. The reflect-array lens of claim 4, wherein an antenna pattern is formed at an outer side of the reflection member formed on the surface opposed to the one surface of the planar dielectric substrate including the plurality of recesses formed thereon.

6. The reflect-array lens of claim 1, wherein the interval between adjacent recesses among the plurality of recesses is smaller than the width of each recess.

7. A solar cell module comprising:
a reflect-array lens including a planar dielectric substrate having a first permittivity and having a plurality of recesses formed thereon and filled with a dielectric having a second permittivity different from the first permittivity; and
a solar cell installed to be spaced apart by a focal distance from the reflect-array lens and converting light concentrated through the reflect-array lens into an electrical signal.

8. The solar cell module of claim 7, wherein a reflection member for reflecting incident light is installed on the surface opposed to the one surface of the planar dielectric substrate including the plurality of recesses formed thereon.

9. The solar cell module of claim 8, wherein an antenna pattern is formed at an outer side of the reflection member formed on the surface opposed to the one surface of the planar dielectric substrate including the plurality of recesses formed thereon.
